(19) United States
(12) Patent Application Publication
(10) Pub. No.: US 2010/0289548 A1
(43) Pub. Date: Nov. 18, 2010

(54) Frequency Generator for Generating Signals with Variable Frequencies

(76) Inventor: Lan-Shan Cheng, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 12/508,556

(22) Filed: Jul. 23, 2009

(30) Foreign Application Priority Data
May 13, 2009 (TW) 098115813

(51) Int. Cl. H03K 7/08

(52) U.S. Cl. 327/176

(57) ABSTRACT

A frequency generator for generating signals with variable frequency includes a periodic signal generator for generating a periodic signal according to an output signal of the frequency generator, a first comparator for comparing the periodic signal and a first reference signal to output a first comparison result, a second comparator for comparing the periodic signal and a second reference signal to output a second comparison result, a logic unit for generating the output signal according to the first comparison result and the second comparison result, and a waveform generator for generating the first reference signal and the second reference signal according to a predetermined frequency variation trend to modulate a output frequency of the output signal.

### BACKGROUND OF THE INVENTION

1. Field of the Invention

The present invention is related to a frequency generator for generating signals with variable frequencies, and more particularly, to a frequency generator capable of adjusting a frequency of an output signal by generating corresponding reference signals according to a predetermined frequency variation trend.

2. Description of the Prior Art

In electronic devices, a frequency generator is a type of signal generator for generating specific frequencies, and is widely employed in synchronization, modulation, demodulation, etc. In general, the frequency generator generates the specific frequencies by means of an oscillating signal.

Please refer to FIG. 1, which is a schematic diagram of an oscillator 10 of the prior art. The oscillator 10 includes a first current source 100, a second current source 102, a first comparator 104, a second comparator 106, an SR flip-flop 108, a switch 110 and a capacitor 112. The first current source 100 and the second current source 102 are respectively utilized for charging and discharging the capacitor 112, to generate a periodic sawtooth signal VT. The first comparator 104 is utilized for comparing the sawtooth signal VT with a high-potential voltage VH and generating a corresponding first comparison result VCMP1. Similarly, the second comparator 106 is utilized for comparing the sawtooth signal VT with a low-potential voltage VL and generating a corresponding second comparison result VCMP2. The SR flip-flop 108 is utilized for generating an output signal VOUT which oscillates periodically according to the first comparison result VCMP1 and the second comparison result VCMP2. The switch 110 is utilized for separating the second current source 102 from the capacitor 112 according to an inverted output signal VOUTB of the output signal VOUT, so as to adjust a frequency of the sawtooth signal VT.

In short, the oscillator 10 generates the sawtooth signal VT by periodically charging and discharging the capacitor 112. The first comparator 104 and the second comparator 106 respectively compare the sawtooth signal VT with the high-potential voltage VH and the low-potential voltage VL, and generate the corresponding comparison results VCMP1, VCMP2, to periodically set or reset the SR flip-flop 108, so as to generate the output signal VOUT which oscillates periodically.

An oscillating frequency of the output signal VOUT is directly proportional to a charging current ICH and inversely proportional to the size of the capacitor 112. Therefore, to vary the oscillating frequency of the output signal VOUT, a circuit designer can change the magnitude of the charging current ICH or the size of the capacitor 112, as respectively illustrated in FIG. 2 and FIG. 3. FIG. 2 is a schematic diagram of an oscillator 20 of the prior art having a tunable frequency. The oscillator 20 is architecturally similar to the oscillator 10 except for extra current sources CUR1-CURn, a micro-controller 200 and switches S1-Sn in the oscillator 20. As a result, the micro-controller 200 can decide whether the current sources CUR1-CURn are electrically linked to the capacitor 112 by controlling the switches S1-Sn, to determine the total magnitude of the charging current ICH, so as to vary the oscillating frequency of the output signal VOUT.

FIG. 3 is a schematic diagram of another oscillator 30 of the prior art having a tunable frequency. The oscillator 30 is also similar to the oscillator 10 except for extra capacitors C1-Cn, a micro-controller 300 and switches S1-Sn. As a result, the micro-controller 300 can decide whether the capacitors C1-Cn are electrically linked to a node n1 by controlling the switches S1-Sn, to determine the total capacitance of a capacitor between the node n1 and a ground, so as to vary the oscillating frequency of the output signal VOUT.

However, a time-variant curve of the oscillating frequency of either of the oscillators 20, 30 is discontinuous, as illustrated in FIG. 4. FIG. 4 is a time-variant schematic diagram of the oscillating frequency of the output signal VOUT of either of the oscillators 20, 30. In FIG. 4, an ideal time-variant curve C_idl is continuously increasing, but an actual time-variant curve C_act of either of the oscillators 20, 30 is increasing step by step. To idealize the actual time-variant curve C_act, the circuit designer has to employ more current sources or capacitors. That is, the more the current sources (capacitors), the better the continuity the oscillating frequency has. However, more current sources or capacitors imply that a larger layout area is required for implementing the oscillators 20, 30. Especially for the oscillator 30, layout area of the circuit would explode due to the extra capacitors.

Therefore, implementing an oscillator having an oscillating frequency which can be continuously varied with smaller layout area has been a major focus of the industry.

### SUMMARY OF THE INVENTION

It is therefore a primary objective of the claimed invention to provide a frequency generator for generating signals with variable frequencies.

The present invention discloses a frequency generator for generating signals with variable frequency. The frequency generator includes a periodic signal generator for generating a periodic signal according to an output signal of the frequency generator, a first comparator coupled to the periodic signal generator for comparing the periodic signal and a first reference signal to output a first comparison result, a second comparator coupled to the periodic signal generator for comparing the periodic signal and a second reference signal to output a second comparison result, a logic unit coupled to the first comparator, the second comparator and the periodic signal generator for generating the output signal according to the first comparison result and the second comparison result, and a waveform generator for generating the first reference signal and the second reference signal according to a predetermined frequency variation trend to modulate an output frequency of the output signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of an oscillator of the prior art.

FIG. 2 is a schematic diagram of an oscillator of the prior art having a tunable frequency.

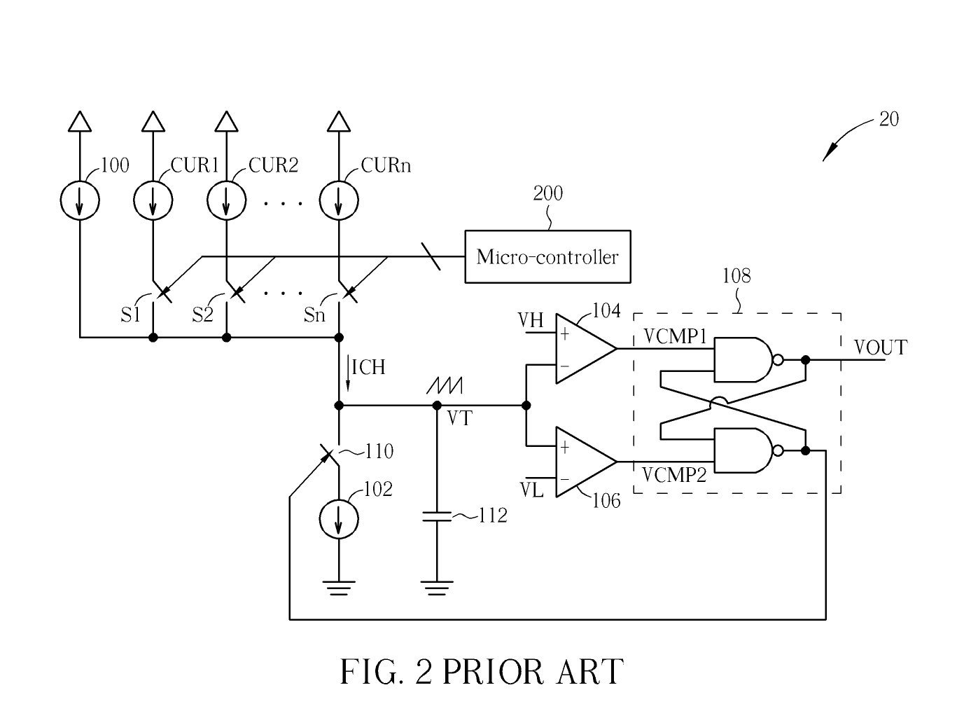

FIG. 3 is a schematic diagram of another oscillator of the prior art having a tunable frequency.

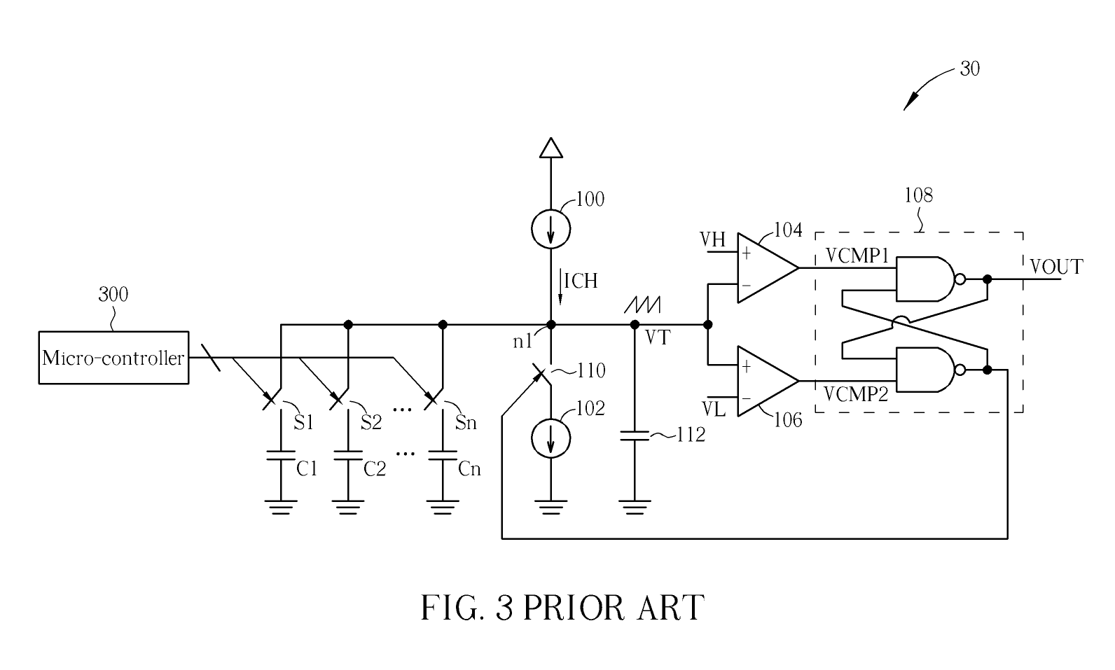

FIG. 4 is a time-variant schematic diagram of an oscillating frequency of an output signal of the oscillator of the prior art.

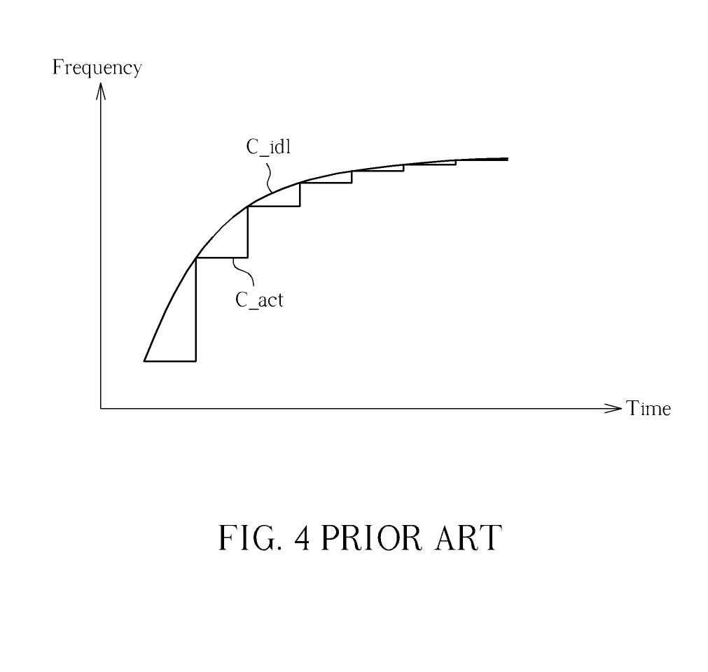

FIG. 5 is a schematic diagram of a frequency generator according to an embodiment of the present invention.

FIG. 6A is a time-variant schematic diagram of signals of the frequency generator of FIG. 5.

FIG. 6B is a time-variant schematic diagram of signals of the frequency generator of FIG. 5.

FIG. 6C is a time-variant schematic diagram of signals of the frequency generator of FIG. 5.

FIG. 7A is a schematic diagram of a sawtooth wave generator according to an embodiment of the present invention.

FIG. 7B is a schematic diagram of a sawtooth wave generator according to an alternative embodiment of the present invention.

### DETAILED DESCRIPTION

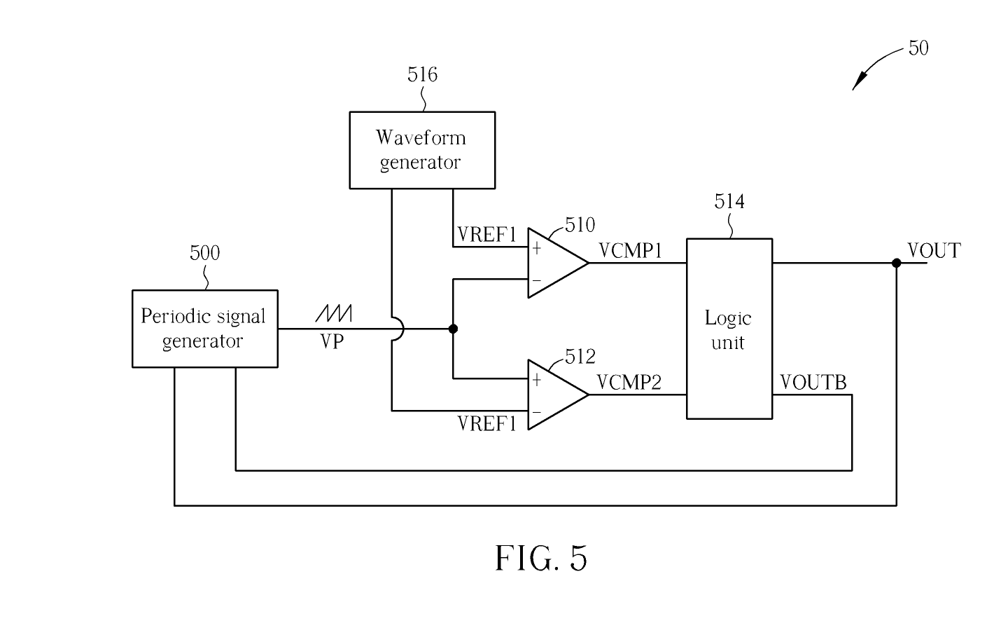

Please refer to FIG. 5, which is a schematic diagram of a frequency generator 50 according to an embodiment of the present invention. The frequency generator 50 is utilized for generating an output signal VOUT with variable frequencies, and includes a periodic signal generator 500, a first comparator 510, a second comparator 512, a logic unit 514 and a waveform generator 516. The periodic signal generator 500 is utilized for generating a periodic signal VP according to the output signal VOUT of the frequency generator 50. The first comparator 510 is utilized for comparing the periodic signal VP and a first reference signal VREF1 to output a first comparison result VCMP1. The second comparator 512 is utilized for comparing the periodic signal VP and a second reference signal VREF2 to output a second comparison result VCMP2. The logic unit 514 is utilized for generating the output signal VOUT according to the first comparison result VCMP1 and the second comparison result VCMP2. The waveform generator 516 is utilized for generating the first reference signal VREF1 and the second reference signal VREF2 according to a predetermined frequency variation trend, to modulate an output frequency of the output signal VOUT.

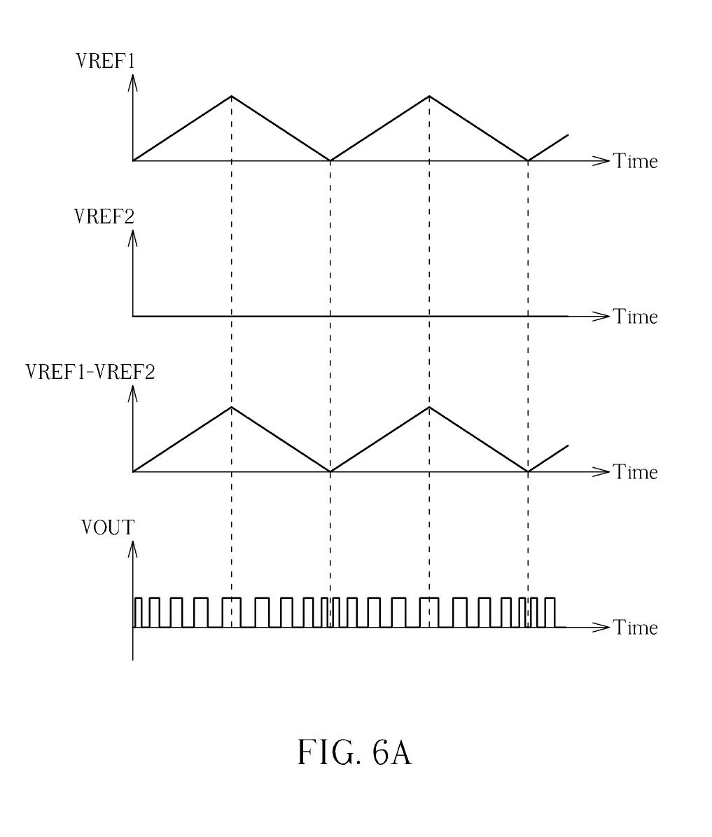

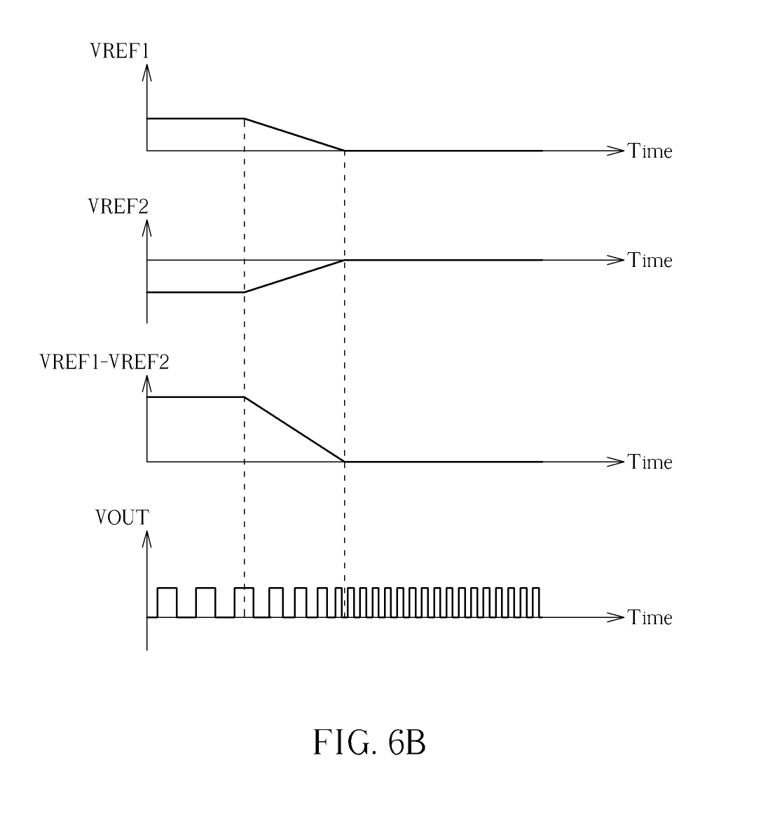

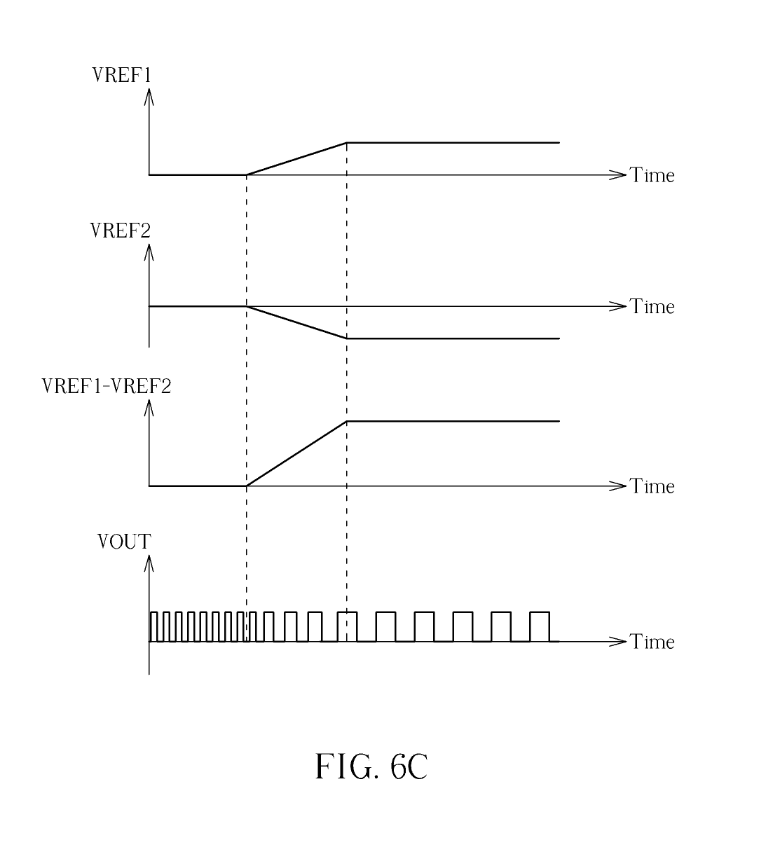

In short, based on the fact that the output frequency is inversely proportional to a difference VREF1−VREF2 between the first reference signal VREF1 and the second reference signal VREF2, the frequency generator 50 first generates the periodic signal VP and takes a frequency thereof as a standard oscillating frequency. Next, the frequency generator 50 compares the periodic signal VP with the first reference signal VREF1 and the second reference signal VREF2, to generate a frequency ranging around the standard oscillating frequency. Note that, the waveform generator 516 can generate the first reference signal VREF1 and the second reference signal VREF2 with various forms to achieve different functions, such as spreading, increasing, or decreasing the frequency, etc. Please refer to FIG. 6A for a more specific illustration of the case of spreading the frequency. FIG. 6A is a time-variant schematic diagram of signals of the frequency generator 50. When designing an alternative embodiment of the frequency generator 50 having an output frequency which oscillates periodically, a circuit designer can set the first reference voltage VREF1 to be a periodic triangle wave and set the second reference voltage VREF2 to be a fixed voltage. Accordingly, the reference voltage difference VREF1−VREF2 is also a periodic triangle wave, and thereby the output frequency oscillates periodically since the output frequency is inversely proportional to the reference voltage difference VREF1−VREF2. In other words, a density of pulses of the output signal VOUT differs with the reference voltage difference VREF1−VREF2, as illustrated in FIG. 6A.

Certainly, the frequency generator 50 not only can adjust either of the reference signals VREF1, VREF2, but can adjust both of the reference signals VREF1, VREF2. Please refer to FIG. 6B for a more specific illustration of the case of increasing the frequency. In FIG. 6B, the waveform generator 516 generates a decreasing first reference signal VREF1 and an increasing second reference signal VREF2, to produce a decreasing reference voltage difference VREF1−VREF2, so as to increase the output frequency. Similarly, please refer to FIG. 6C for a more specific illustration of the decreasing frequency case. In FIG. 6C, the circuit designer can produce an increasing reference voltage difference VREF1−VREF2, so as to decrease the output frequency.

As mentioned in the above, to vary the output frequency of the frequency generator 50, waveforms of the first reference signal VREF1 and the second reference signal VREF2 may be “customized” by the waveform generator 516, so as to vary the output frequency correspondingly.

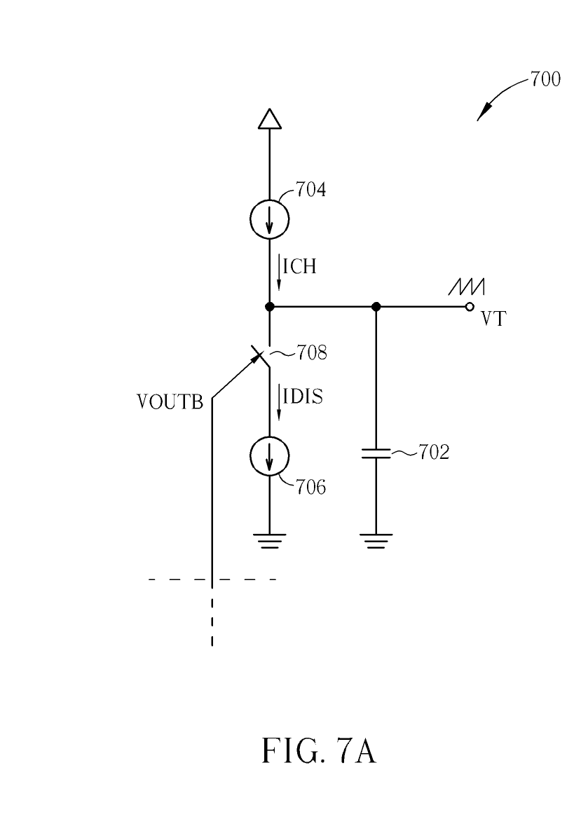

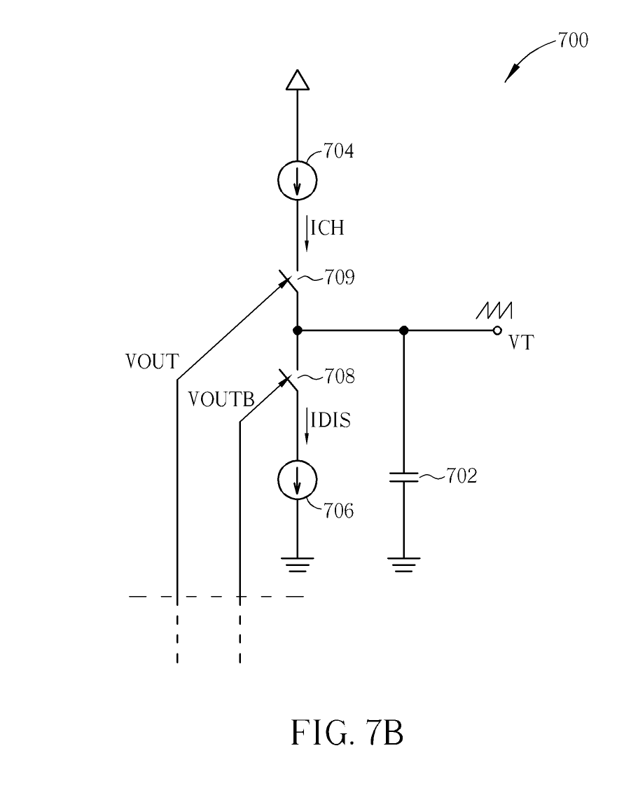

On the other hand, in FIG. 5, the periodic signal generator 500 utilized for generating the periodic signal VP can preferably be a sawtooth wave generator. For example, please refer to FIG. 7A, which is a schematic diagram of a sawtooth wave generator 700 according to an embodiment of the present invention. The sawtooth wave generator 700 is utilized for generating a sawtooth signal VT as the periodic signal VP, and includes a capacitor 702, a first current source 704, a second current source 706 and a first switch 708. The first current source 704 is utilized for outputting a charging current ICH to the capacitor 702. The second current source 706 is utilized for pumping a discharging current IDIS from the capacitor 702. The first switch 708 is utilized for separating the second current source 706 from the capacitor 702 according to an inverted output signal VOUTB of the output signal VOUT.

In short, the sawtooth wave generator 700 charges the capacitor 702 by the first current source 704, and regularly controls the first switch 708 according to the output frequency of the output signal VOUT, such that the capacitor 702 can periodically discharge through the second current source 706, so as to generate the periodically-varied sawtooth signal VT.

In addition, the sawtooth wave generator 700 can further include a second switch 709, as illustrated in FIG. 7B. The second switch 709 is utilized for separating the first current source 704 from the capacitor 702 according to the output signal VOUT. As a result, the sawtooth wave generator 700 can periodically alternate between a charging state and a discharging state, so as to generate the periodically-varied sawtooth signal VT.

In addition to the sawtooth wave generator 700, the periodic signal generator can further be a sinusoidal wave generator for generating a sinusoidal signal as the periodic signal VP. With the sinusoidal wave generator, the frequency generator 50 can achieve exactly the same objective of varying the output frequency, just as with the sawtooth wave generator 700. The sinusoidal wave generator is well-known to those skilled in the art, and is not further narrated herein.

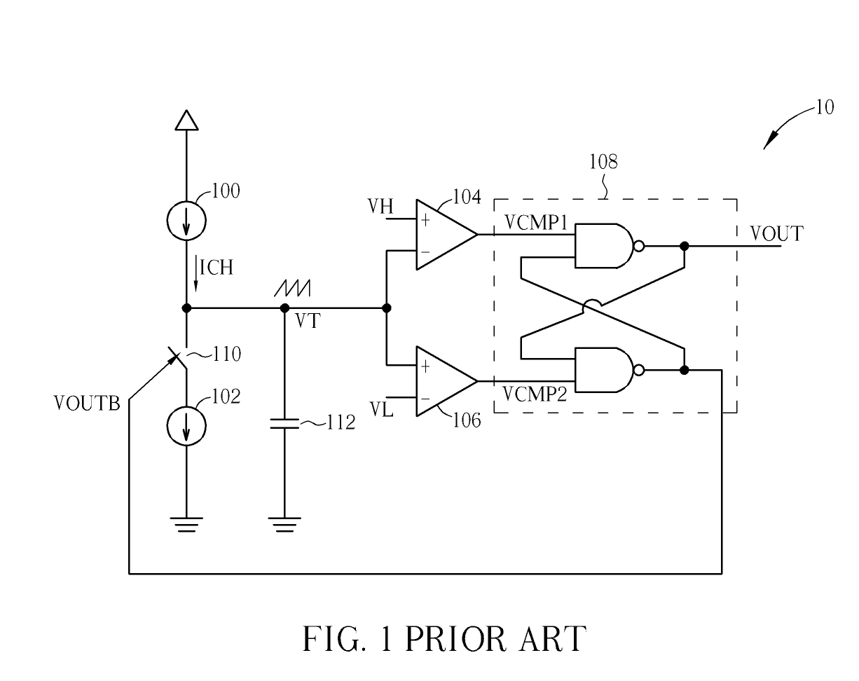

In FIG. 5, the logic unit 514 can preferably be an SR flip-flop, just as the SR flip-flop 108 of FIG. 1, to latch the first comparison result VCMP1 and the second comparison result VCMP2 and generate the output signal VOUT and the inverted output signal VOUTB.

In the prior art, to improve the disadvantage that the output frequencies of the oscillators 20, 30 can only be discontinuously varied, the circuit designer has to include more capacitors or current sources. For that reason, the circuit layout area of either of the oscillators 20, 30 would increase remarkably. Especially for the oscillator 30, extra capacitors would increase the circuit layout area dramatically. In comparison, the present invention utilizes the fact that the output frequency is inversely proportional to the reference voltage difference VREF1−VREF2, and thereby adjusts the first reference voltage VREF1 and the second reference voltage VREF2, to generate the continuously-varied output frequency based on different requirements. Hence, the continuity of the time-variant curve of the output frequency is no longer limited by physical circuits.

To sum up, for the frequency generator, the present invention can enhance the continuity of output frequency variation. Meanwhile, for various frequency variation trends, the present invention can achieve desired functions by designing different reference signals.

Those skilled in the art will readily observe that numerous modifications and alterations of the device and method may be made while retaining the teachings of the invention.

What is claimed is:

1. A frequency generator for generating signals with variable frequency comprising:
a periodic signal generator, for generating a periodic signal according to an output signal of the frequency generator;
a first comparator, coupled to the periodic signal generator, for comparing the periodic signal and a first reference signal, to output a first comparison result;
a second comparator, coupled to the periodic signal generator, for comparing the periodic signal and a second reference signal to output a second comparison result;
a logic unit, coupled to the first comparator, the second comparator and the periodic signal generator, for generating the output signal according to the first comparison result and the second comparison result; and
a waveform generator, for generating the first reference signal and the second reference signal according to a predetermined frequency variation trend, to modulate an output frequency of the output signal.

2. The frequency generator of claim 1, wherein the periodic signal generator is a sawtooth wave generator, for generating a sawtooth signal as the periodic signal.

3. The frequency generator of claim 2, wherein the sawtooth wave generator comprises:
a capacitor;
a first current source, coupled to the capacitor, for outputting a charging current to the capacitor;
a second current source, for pumping a discharging current; and
a first separation device, coupled to the logic unit, the second current source and the capacitor, for separating the second current source from the capacitor according to the output signal.

4. The frequency generator of claim 3, wherein the sawtooth wave generator further comprises:
a second separation device, coupled to the logic unit, the first current source and the capacitor, for separating the first current source from the capacitor according to the output signal.

5. The frequency generator of claim 1, wherein the periodic signal generator is a sinusoidal wave generator, for generating a sinusoidal signal as the periodic signal.

6. The frequency generator of claim 1, wherein the logic unit is an SR flip-flop.

7. The frequency generator of claim 1, wherein the first reference signal generated by the waveform generator is varied according to the predetermined frequency variation trend.

8. The frequency generator of claim 7, wherein the second reference signal generated by the waveform generator is fixed.

9. The frequency generator of claim 7, wherein the second reference signal generated by the waveform generator is varied according to the predetermined frequency variation trend.

10. The frequency generator of claim 1, wherein the second reference signal generated by the waveform generator is varied according to the predetermined frequency variation trend.

11. The frequency generator of claim 10, wherein the first reference signal generated by the waveform generator is fixed.

12. The frequency generator of claim 10, wherein the first reference signal generated by the waveform generator is varied according to the predetermined frequency variation trend.
